(19) United States
(12) Patent Application Publication
(10) Pub. No.: US 2008/0172867 A1
(43) Pub. Date: Jul. 24, 2008

(54) METHOD OF MANUFACTURING MULTI-LAYERED FLEXIBLE PRINTED CIRCUIT BOARD

(75) Inventors: Koji Tsurusaki, Sakura-shi (JP); Fumitaka Aizawa, Sakura-shi (JP); Osamu Nakao, Sakura-shi (JP)

Correspondence Address: SUGHRUE MION, PLLC, 2100 PENNSYLVANIA AVENUE, N.W., SUITE 800, WASHINGTON, DC, 20037, US

(73) Assignee: FUJIKURA LTD., Tokyo (JP)

(21) Appl. No.: 11/845,544

(22) Filed: Aug. 27, 2007

(30) Foreign Application Priority Data
Sep. 7, 2006 (JP) 2006-242673

(51) Int. Cl. H05K 3/36

(52) U.S. Cl. 29/830; 29/829; 29/831

(57) ABSTRACT

Provided is a method of manufacturing a multi-layered flexible print circuit board (FPC), which is capable of preventing an adhesive member of the multi-layered FPC from being peeled from FPCs. The invention provides a method of manufacturing a multi-layered flexible printed circuit board (multi-layered FPC) including laminating at least two flexible printed circuit boards laminated,

wherein a side comprising a conductor circuit in which a conductor circuit of at least one of the at least two flexible printed circuit boards before being laminated is present is subject to an alkaline solution with a concentration of 0.2 to 6.0 wt % and a temperature of 20 to 45° C. under a treatment time of 20 to 100 seconds before the laminating.

### CROSS-REFERENCE TO RELATED APPLICATIONS

This application claims priority from Japanese Patent Application No. 2006-242673, filed in the Japanese Patent Office on Sep. 7, 2006, the disclosure of which is incorporated herein by reference.

### BACKGROUND OF THE INVENTION

1. Field of the Invention

The present invention relates to a method of manufacturing a multi-layered flexible print circuit board (multi-layered FPC) including at least two flexible printed circuits (FPCs), and more particularly, to a method of manufacturing a multi-layered flexible print circuit board with high yield and reliability, which is capable of preventing a chemical solution used in a post-laminating process from penetrating into a substrate by improving adhesion strength with an alkaline process to prevent the inside of the substrate from being peeled.

2. Description of the Related Art

In the related art, a printed circuit board employing a copper clad laminate (CCL) has been used in electronic devices and so on. As such a printed circuit board, FPC, RPC (Rigid Printed Circuit), a R-F (Rigid-Flexible) board which is a combination of RPC and FPC, etc are known.

In recent years, a multi-layered flexible printed circuit board (multi-layered FPC) has been employed including only FPC for weight reduction and thinness.

A multi-layered FPC employs a structure in which a plurality of members made of different materials is arranged in combination or laminated to each other. Therefore, if adhesion between particular members is weak, there is a possibility of peeling between the particular members in environmental tests such as heat cycling or with temporal change. For example, if there is peeling between the copper clad and polyimide (PI) or between the copper clad and an adhesive, it is not suitable for use as a printed circuit board because of loss in insulation properties. Accordingly, there is a need to attach the members to each other with appropriate adhesion in the multi-layered FPC.

In a conventional method of manufacturing the multi-layered FPC, there may be a case where an attachment portion of an adhesive member at which two or more FPCs are attached to each other has a weak adhesive strength. In this case, the FPCs are apt to be separated from each other. This separation may allow a chemical solution used for etching or developing to penetrate between the FPCs in processes following the attaching process, which may result in a significant decrease in reliability of multi-layered FPCs as industrial products.

Methods for improving an adhesive strength of a polyimide may include (I) a method of modifying a polyimide surface by alkaline treatment after treating the polyimide surface to be electrically discharged (JP-A-5-279497), (II) a method of modifying a polyimide surface by alkaline solution after subjecting the polyimide surface to plasma treatment at low temperature (JP-A-6-032926), (III) a method of modifying a polyimide film surface by an aqueous acidic solution after subjecting the surface to alkaline aqueous solution treatment (JP-A-7-003055), (IV) a method of modifying a polyimide film surface by plasma treatment after subjecting the surface to plasma treatment in an inert gas (JP-A-8-003338), and (V) a method of modifying a polyimide resin surface by etching with a second oxidizing agent after irradiating the polyimide resin surface with ultraviolet rays in the presence of a first oxidizing agent (JP-A-9-157417).

However, the above-mentioned publications (I) to (V) disclose only that a surface is subjected to alkaline or plasma treatment for improving adhesiveness, but do not specify detailed treatment conditions such as concentration, temperature of the alkaline solution and treatment time. In other words, these publications have no disclosure for optimum conditions of surface treatment for each condition.

In addition, there has been proposed (VI) a multi-layered printed circuit board suitable for heat-resistant flip-chip mounting, and a method of manufacturing the same (JP-A-9-298369). This publication discloses an appropriate range of modulus of elasticity and coefficient of linear expansion of an adhesive layer and composition of an adhesive.

In addition, there has been proposed (VII) a multi-layered printed circuit board in which a via hole is hardly peeled from a lower layer of a conductor circuit (JP-A-11-046066). This publication discloses an appropriate range of particle diameter and weight proportion of an epoxy resin as an adhesive layer.

In addition, there has been proposed (VIII) a multi-layered printed circuit board having excellent adhesive strength between a conductor layer and an insulating layer, but the publication merely discloses a surface roughening treatment method (Japanese Patent Application Publication No. Hei 10-070367).

In addition, there has been proposed (IX) an adhesive for a flexible printed circuit board and a composition of the adhesive (JP-A-2001-164226).

However, although the above-mentioned publications (VI) to (IX) disclose adhesives used in conventional printed circuit boards in which the kind and proportion of the adhesives and a surface treatment are specified for prevention of peeling of the adhesive and increasing the an adhesive strength, these publications do not disclose an alkaline treatment, in particular, there are no disclosures of improving adhesiveness under optimum conditions of alkaline treatment.

In addition, there has been proposed (X) a rigid-flexible printed circuit board with increased adhesion and the optimum conditions of an alkaline treatment (JP-A-2006-15676).

However, the above-mentioned publication (X) is only for a rigid-flexible printed circuit board and moreover for only sites of attachment of an inner layer substrate to an outer layer substrate and does not specify other attachment sites.

### SUMMARY OF THE INVENTION

Exemplary embodiments of the present invention overcome the above disadvantages and other disadvantages not described above. Also, the present invention is not required to overcome the disadvantages described above, and an exemplary embodiment of the present invention may not overcome any of the problems described above.

In recent years, with increased lightness, thinness, shortness and smallness of electronic devices, there has been a need of a printed circuit board with high density interconnections. Since a FPC has a base thinner than an RPC and is advantageous to formation of a fine circuit over the RPC, a multi-layered FPC is sufficient to satisfy the need. Accordingly, it is expected to establish specific treatment conditions for a method of treating a member surface to provide an adhesive in the multi-layered FPC.

Under such circumstances, it is an object to provide a method of manufacturing a multi-layered flexible print circuit board (FPC) including at least two flexible printed circuit boards, which is capable of preventing an adhesive member from being peeled from a FPC.

To achieve the above object, the invention provides a method of manufacturing a multi-layered flexible printed circuit board having at least two flexible printed circuit boards laminated. In the method, a side in which a conductor circuit of the flexible printed circuit boards before being laminated is present is subject to an alkaline treatment under conditions of an alkaline solution with a concentration of 0.2 to 6.0 wt %, temperature of 20 to 45° C. and treatment time of 20 to 100 seconds.

Preferably, the flexible printed circuit boards subject to the alkaline treatment are laminated by attachment using an interlayer adhesive or a prepreg or coverlay film.

According to the invention, it is possible to provide a method of manufacturing a multi-layered FPC including two or more FPCs laminated, which is capable of increasing adhesion strength of an attachment portion and preventing an interlayer peeling, which results in improvements of yield and reliability of the multi-layered FPC.

### BRIEF DESCRIPTION OF THE DRAWINGS

The above and/or other objects of the present invention will be more apparent by describing certain exemplary embodiments of the present invention with reference to the accompanying drawings, in which:

FIG. 1A is a sectional view showing an example of a process of manufacturing a four-layered FPC in order according to an exemplary embodiment of the present invention.

FIG. 1B is a sectional view showing an example of a process of manufacturing a four-layered FPC in order according to an exemplary embodiment of the present invention.

FIG. 1C is a sectional view showing an example of a process of manufacturing a four-layered FPC in order according to an exemplary embodiment of the present invention.

FIG. 1D is a sectional view showing an example of a process of manufacturing a four-layered FPC in order according to an exemplary embodiment of the present invention.

FIG. 2A is a cross-sectional view showing an example of a process of manufacturing an inner substrate in order according to an exemplary embodiment of the present invention.

FIG. 2B is a cross-sectional view showing an example of a process of manufacturing an inner substrate in order according to an exemplary embodiment of the present invention.

FIG. 2C is a cross-sectional view showing an example of a process of manufacturing an inner substrate in order according to an exemplary embodiment of the present invention.

FIG. 3A is a cross-sectional view showing an example of a process of manufacturing an outer substrate in order according to an exemplary embodiment of the present invention.

FIG. 3B is a cross-sectional view showing an example of a process of manufacturing an outer substrate in order according to an exemplary embodiment of the present invention.

FIG. 4A is a cross-sectional view showing an example of a process of manufacturing a six-layered FPC in order according to an exemplary embodiment of the present invention.

FIG. 4B is a cross-sectional view showing an example of a process of manufacturing a six-layered FPC in order according to an exemplary embodiment of the present invention.

FIG. 4C is a cross-sectional view showing an example of a process of manufacturing a six-layered FPC in order according to an exemplary embodiment of the present invention.

FIG. 4D is a cross-sectional view showing an example of a process of manufacturing a six-layered FPC in order according to an exemplary embodiment of the present invention.

FIG. 4E is a cross-sectional view showing an example of a process of manufacturing a six-layered FPC in order according to an exemplary embodiment of the present invention.

FIG. 5A is a cross-sectional view showing an example of a process of manufacturing an outermost substrate in order according to an exemplary embodiment of the present invention.

FIG. 5B is a cross-sectional view showing an example of a process of manufacturing an outermost substrate in order according to an exemplary embodiment of the present invention.

FIG. 6 is a graph showing a result of Example 1.

FIG. 7 is a graph showing a result of Example 2.

FIG. 8 is a graph showing a result of Example 3.

### DETAILED DESCRIPTION OF THE INVENTION

Hereinafter, the invention will be described through exemplary embodiments with reference to the accompanying drawings.

A method of manufacturing a multi-layered FPC according to the exemplary embodiments of the present invention includes subjecting surfaces of at least two FPCs to an alkaline treatment before the FPCs are laminated by means of an adhesive member or the like. This method is applicable to a case where a plurality of FPCs is laminated in one step (single-step lamination) and a case where a plurality of FPCs are laminated one by one or several by several (multi-step lamination).

In the invention, the alkaline treatment is carried out under conditions of an alkaline solution concentration of 0.2 to 6.0 wt %, temperature of 20 to 45° C. and treatment time of 20 to 100 seconds. This alkaline treatment increases adhesion strength of an attachment portion to prevent an inner layer from being peeled from an outer layer. The alkaline solution may include, for example, sodium hydroxide aqueous solution [NaOH(aq)] and the like without being limited thereto. After the alkaline treatment, it is preferable to carry out a washing treatment to prevent alkaline deposition.

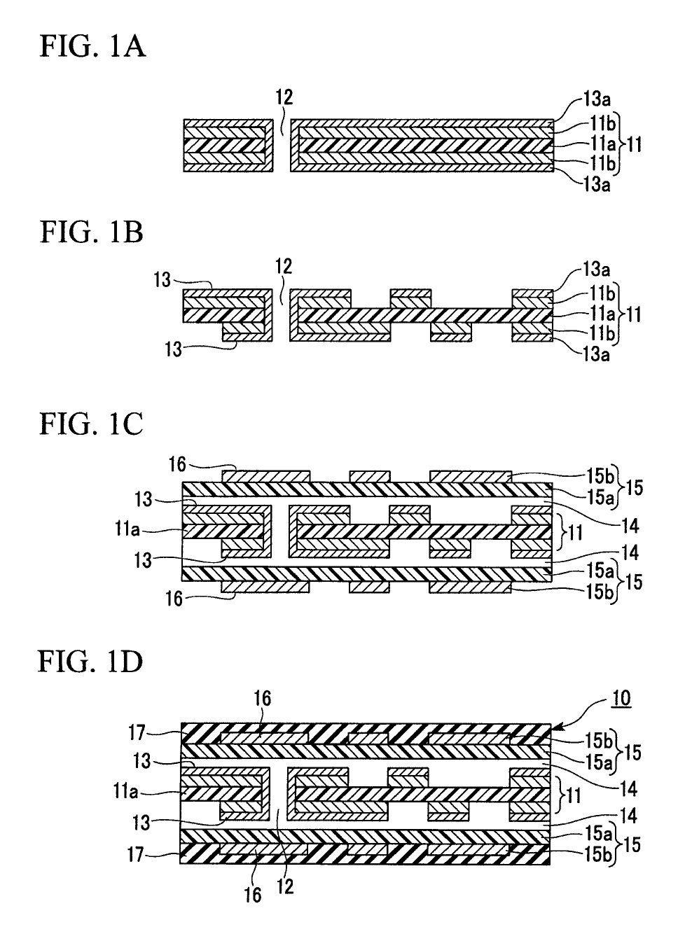

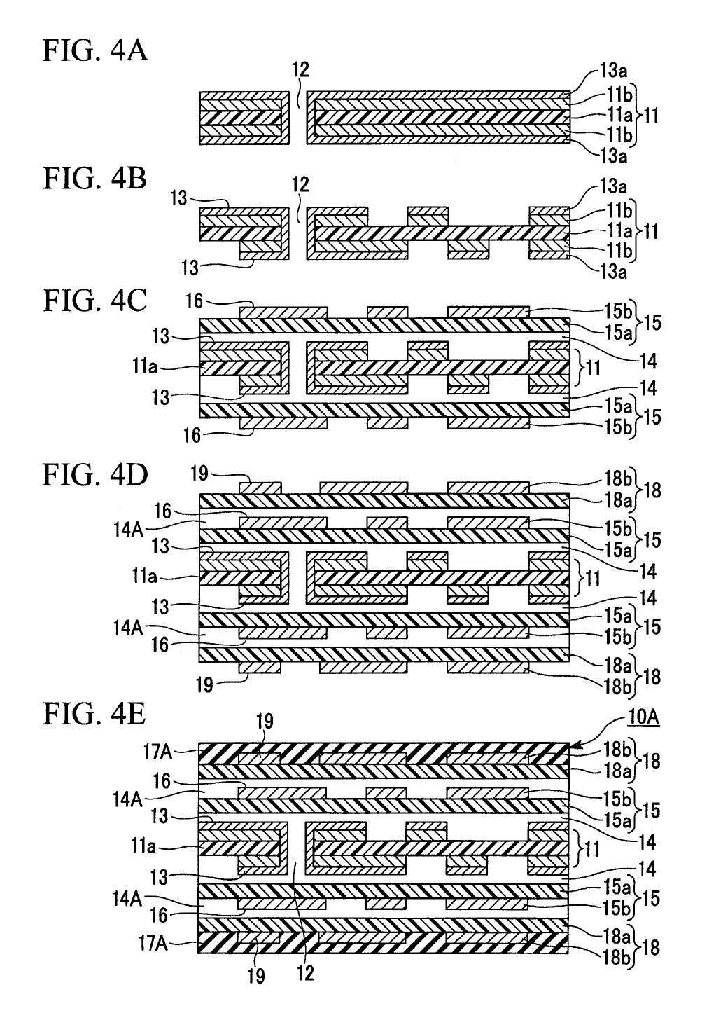

The multi-layered FPC of the invention is not particularly limited in substrate size, material thickness, layer number, configuration and so on. An example of a structure of the multi-layered FPC may include a 4-layered flexible printed circuit board (4-layered FPC) shown in FIG. 1D and a 6-layered flexible printed circuit board (6-layered FPC) shown in FIG. 4E without being limited thereto.

A multi-layered FPC (4-layered FPC) 10 shown in FIG. 1D includes an inner layer substrate 11 having circuits 13 and 13 formed on its both sides, two outer substrates 15 and 15 having circuits 16 formed on their one sides, and interlayer adhesives 14 and 14 that adhere the inner layer substrate 11 and the outer layer substrate 15 and 15, and resist layers 17 formed on surfaces of the outer layer substrates 15 and 15. The two outer layer substrates 15 and 15 are attached to the both sides (upper and lower sides in FIGS. 1A to 1D) of the inner layer substrate 11 via the interlayer adhesives 14 and 14, respectively. In the multi-layered FPC 10, interlayer conduction between circuits of the inner layer substrate 11 is achieved by a plating layer 13a including an inner side of a through-hole 12 formed in the inner layer substrate 11.

An exemplary embodiment of the method of manufacturing the multi-layered FPC 10 shown in FIGS. 1A to 1D may include a manufacturing process as described below.

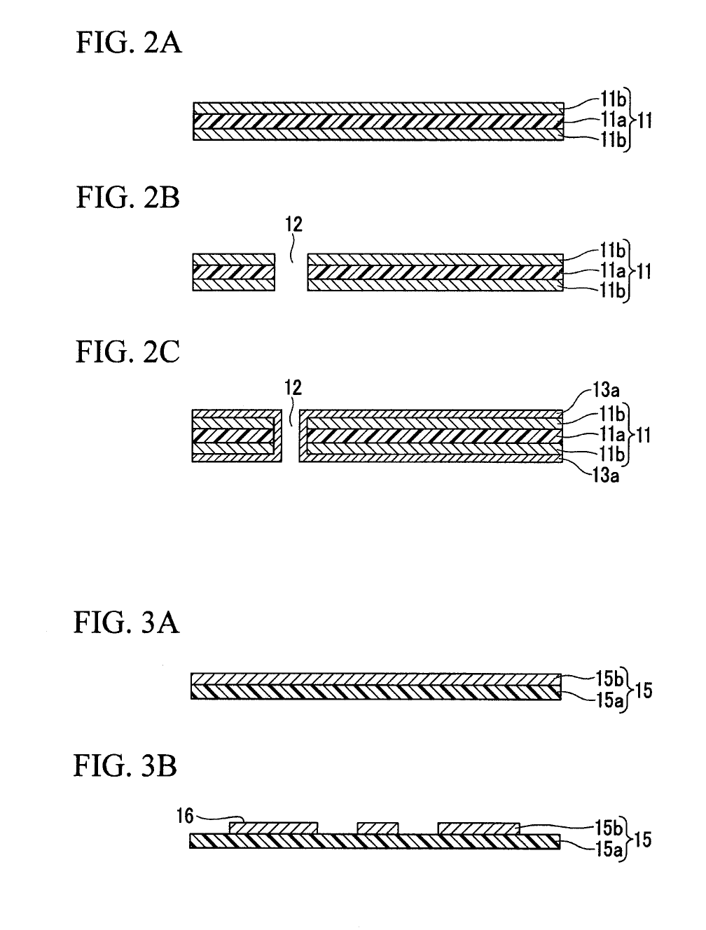

In an exemplary embodiment of the invention, the inner layer substrate 11 is comprised of a double-sided copper clad laminate (both-sided CCL) 11, thus the inner layer substrate 11 is also called as both-sided CCL 11. First, for the inner layer substrate 11, the both-sided CCL 11 having copper foils 11b and 11b laminated on both sides of a flexible insulating base 11a made of an insulating resin such as a polyimide is prepared, as shown in FIG. 2A, and the through-hole 12 is formed at a predetermined position on the both-sided CCL 11, as shown in FIG. 2B. Here, in the both-sided CCL 11, the insulating base 11a may be laminated on the copper foils 11b directly or via an adhesive (not shown).

Next, as shown in FIGS. 2C and 1A, the plating layer 13a is plated on the inner side of the through-hole 12 and both of copper foils 11b. The plating layer 13a secures conduction between the circuits 13 and 13 of the both sides of the inner layer substrate 11. The plating layer 13a may be plated one or more times.

Next, as shown in FIG. 1B, the inner layer circuits 13 are formed by patterning an inner conductive layer including the copper foils 11b and the plating layer 13a.

After forming the inner layer circuits 13, the insulating base 11a of the inner layer substrate 11 is subject to an alkaline treatment. The alkaline treatment is carried out under conditions of an alkaline solution concentration of 0.2 to 6.0 wt %, temperature of 20 to 45° C. and treatment time of 20 to 100 seconds. This alkaline treatment increases adhesion strength of an attachment portion to prevent an inner layer from being peeled from an outer layer.

In the invention, the outer layer substrate 15 is comprised of a single-sided copper clad laminate (single-sided CCL) 15, thus the outer layer substrate 15 is also called as single-sided CCL 15. As shown in FIG. 3A, for the outer layer substrates 15, an outer layer circuit 16 is formed by patterning a copper foil 15b, as shown in FIG. 3B, using the single-sided CCL 15 having the copper foil 15b formed on one side of a flexible insulating base 15a made of an insulating resin such as a polyimide, as shown in FIG. 3A.

In the single-sided CCL, the insulating base 15a may be laminated on the copper foil 15b directly or via an adhesive (not shown).

The outer layer substrates 15 shown in FIG. 3B are laminated on both sides of the inner layer substrate 11 shown in FIG. 1B via the interlayer adhesives 14, respectively (see FIG. 1C). At this time, since a surface of the insulating base 11a at the circuit 13 side of the inner layer substrate 11 increases in adhesion by the alkaline treatment, the interlayer adhesives 14 are hardly peeled off, and a chemical solution (used for etching or plating) is prevented from penetrating into the substrate in subsequent processes, which may result in improvement of yield and reliability of multi-layered FPC.

Finally, the resist layers 17 are formed at predetermined positions of the outer layer substrates 15, thereby completing the multi-layered FPC 10 shown in FIG. 1D.

A multi-layered FPC (6-layered FPC) 10A shown in FIG. 4E includes an inner layer substrate 11 having circuits 13 and 13 formed on its both sides, two outer substrates 15 and 15 having circuits 16 formed on their one sides, and first interlayer adhesives 14 and 14 that adhere the inner layer and the outer layer, two outermost layer substrates 18 and 18 having circuits 19 formed on their one sides, second interlayer adhesives 14A and 14A that adhere the outer layer and the outermost layer, and resist layers 17A formed on surfaces of the outermost layer. The two outer layer substrates 15 and 15 are attached to the both sides (upper and lower sides in FIGS. 1A to 1D) of the inner layer substrate 11 via the first interlayer adhesives 14, respectively, and the two outermost layer substrates 18 and 18 are attached to the outer layer substrates 15 via the second interlayer adhesives 14A, respectively. In the multi-layered FPC 10A, interlayer conduction between circuits of the inner layer substrate 11 is achieved by a plating layer 13a including an inner side of the through-hole 12 formed in the inner layer substrate 11.

An exemplary embodiment of the method of manufacturing the multi-layered FPC 10A shown in FIGS. 4A to 4E may include a manufacturing process as described below.

Since the inner layer substrate 11 can be manufactured in the same way as the inner layer substrate 11 of the above-described 4-layered FPC 10, repeated description thereof will be omitted. Also for the 6-layered FPC 10A, after forming the inner layer circuits 13, the insulating base 11a of the inner layer substrate 11 is subject to an alkaline treatment. The alkaline treatment is carried out under conditions of an alkaline solution concentration of 0.2 to 6.0 wt %, temperature of 20 to 45° C. and treatment time of 20 to 100 seconds. This alkaline treatment increases adhesion strength of an attachment portion to prevent delamination between an inner layer and an outer layer.

As shown in FIG. 3A, for the outer layer substrates 15, an outer layer circuit 16 is formed by patterning a copper foil 15b, as shown in FIG. 3B, using a single-sided copper clad laminate (single-sided CCL) 15 having the copper foil 15b formed on one side of a flexible insulating base 15a made of an insulating resin such as a polyimide, as shown in FIG. 3A.

In addition, for the 6-layered FPC 10A, after forming the outer layer circuits 16, the insulating base 15a of the outer layer substrate 15 is subject to an alkaline treatment. The alkaline treatment is carried out under conditions of an alkaline solution concentration of 0.2 to 6.0 wt %, temperature of 20 to 45° C. and treatment time of 20 to 100 seconds. This alkaline treatment increases adhesion strength of an attachment portion to prevent delamination between the outer layer and an outermost layer.

In the single-sided CCL, the insulating base 15a may be laminated on the copper foil 15b directly or via an adhesive (not shown).

The outer layer substrates 15 are laminated on both sides of the inner layer substrate 11 shown in FIG. 4B via the interlayer adhesives 14, respectively (see FIG. 4C). At this time, since a surface of the insulating base 11a at the circuit 13 side of the inner layer substrate 11 increases in adhesion by the alkaline treatment, the first interlayer adhesives 14 is hardly peeled off, and a chemical solution (used for etching or plating) is prevented from penetrating into the substrate in subsequent processes, which may result in improvement of yield and reliability of multi-layered FPC.

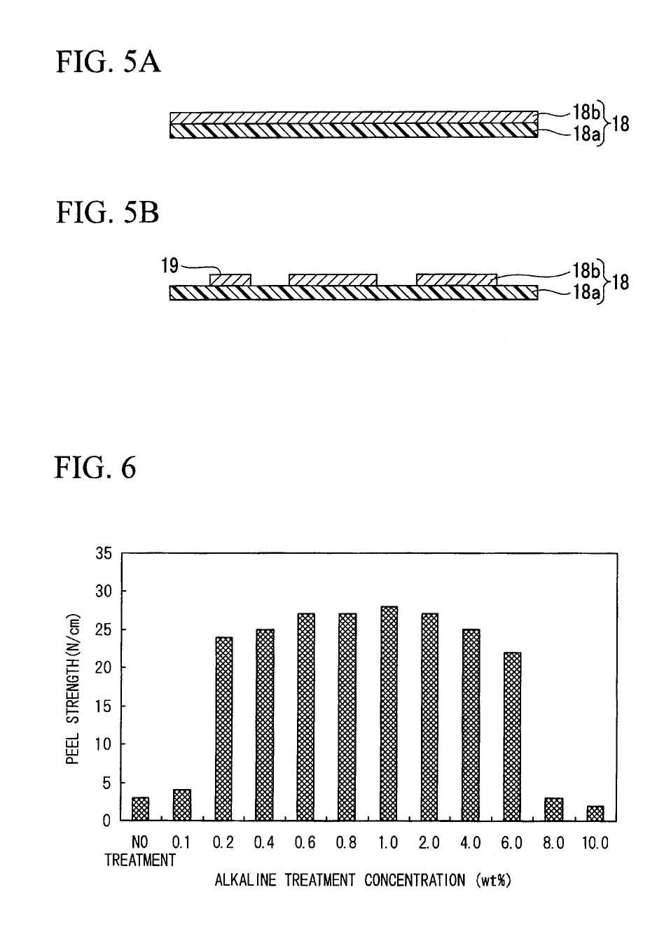

As shown in FIG. 5A, for the outermost layer substrates 15, the outer layer circuit 16 is formed by patterning a copper foil 18b, as shown in FIG. 5B, using a single-sided copper clad laminate (single-sided CCL) 18 having the copper foil 18b formed on one side of a flexible insulating base 18a made of an insulating resin such as a polyimide, as shown in FIG. 5A.

In the single-sided CCL, the insulating base 18a may be laminated on the copper foil 18b directly or via an adhesive (not shown).

The outermost layer substrates 18 are laminated on both sides of the outer layer substrates 15 shown in FIG. 4C via the second interlayer adhesives 14A, respectively (see FIG. 4D). At this time, since a surface of the insulating base 15a at the side of the circuit 16 of the outer layer substrate 15 increases in adhesion by the alkaline treatment, the second interlayer adhesives 14A are hardly peeled off, and a chemical solution (used for etching or plating) is prevented from penetrating into the substrate in subsequent processes, which may result in improvements of yield and reliability of multi-layered FPC.

Finally, the resist layers 17A are formed at predetermined positions of the outermost layer substrates 18, thereby completing the multi-layered FPC 10A shown in FIG. 4E.

### EXAMPLES

Hereinafter, the invention will be described in detail through examples without being limited thereto.

In the following examples, a 6-layered FPC having a structure in which two each of single-sided FPCs 15 and 18 are laminated on surfaces of the both-sided FPC 11 according to the same method as in FIGS. 4A to 4E is manufactured.

### Example 1

Composition:

Both-sided CCL; model number: PKW, copper foil thickness: 18 μm, polyimide thickness: 25 μm, which is available from Arisawa Manufacturing Co., Ltd.

Single-sided CCL; model number: PNS, copper foil thickness: 18 μm, polyimide thickness: 25 μm, which is available from Arisawa Manufacturing Co., Ltd.

Interlayer adhesive; model number: SAFD, adhesive thickness: 25 μm, which is available from Nikkan Industries Co., Ltd.

Resist; model number: AUS, resist thickness: 25 μm, which is available from Taiyo Ink Co., Ltd.
Alkaline treatment conditions:

Sodium hydroxide (NaOH) aqueous solution was used as the alkaline solution for alkaline treatment.

Concentration of the alkaline solution was varied in a range of 0.1 to 10.0 wt % (at 11 different measurement points). Irrespective of the concentration, the treatment time was 30 seconds and temperature of the chemical solution was 25° C.

RO water (water purified by a reverse osmotic membrane) was used for rinsing after alkaline treatment. Temperature of RO water was at the room temperature and washing time was 30 seconds.

### Example 2

Composition was the same as Example 1.
Alkaline treatment conditions:

Sodium hydroxide (NaOH) aqueous solution was used as the alkaline solution for alkaline treatment.

Alkaline treatment time was varied in a range of 10 to 600 seconds (at 11 different measurement points). Irrespective of the treatment time, concentration of the solution was 1.0 wt % and temperature of the chemical solution was 25° C.

RO water (water purified by a reverse osmotic membrane) was used for rinsing after alkaline treatment. Temperature of RO water was at room temperature and washing time was 30 seconds.

### Example 3

Composition was the same as Example 1.
Alkaline treatment conditions:

Sodium hydroxide (NaOH) aqueous solution was used as the alkaline solution for alkaline treatment.

Temperature of the alkaline solution was varied in a range of 5 to 55° C. (at 11 different measurement points). Irrespective of the temperature of the solution, the solution concentration was 1.0 wt % and treatment time was 30 seconds.

RO water (water purified by a reverse osmotic membrane) was used for rinsing after alkaline treatment. Temperature of RO water was at room temperature and washing time was 30 seconds.

### Conventional Example

### No Treatment

Composition was the same as Example 1.
A multi-layered FPC was manufactured according to the same method as the examples except that alkaline treatment was not carried out.

### Test Example

A peel strength test based on Japanese Industrial Standard (JIS) C 6471 was carried out for samples obtained from the examples. Tensile speed was 50 mm/min and test temperature was normal temperature (at room temperature). A peel strength (in the unit of N/cm) was calculated based on JIS C 5016 8.1.6. The number of measurement sites was four: between the insulating base 18a of the outermost layer substrate 18 and the circuit 16 of the outer layer substrate 15 at the front side (between an L1 layer and an L2 layer), between the insulating base 15a of the outer layer substrate 15 and the circuit 13 of the inner layer substrate 11 at the front side (between the L2 layer and an L3 layer), between the insulating base 18a of the outermost layer substrate 18 and the circuit 16 of the outer layer substrate 15 at the rear side (between an L5 layer and an L6 layer), and between the insulating base 15a of the outer layer substrate 15 and the circuit 13 of the inner layer substrate 11 at the rear side (between the L3 layer and an L4 layer).

Here, the L1 to L6 layers refer to 6 layer circuits 19, 16, 13, 13, 16 and 19 from the top to the bottom in FIG. 4E, respectively.

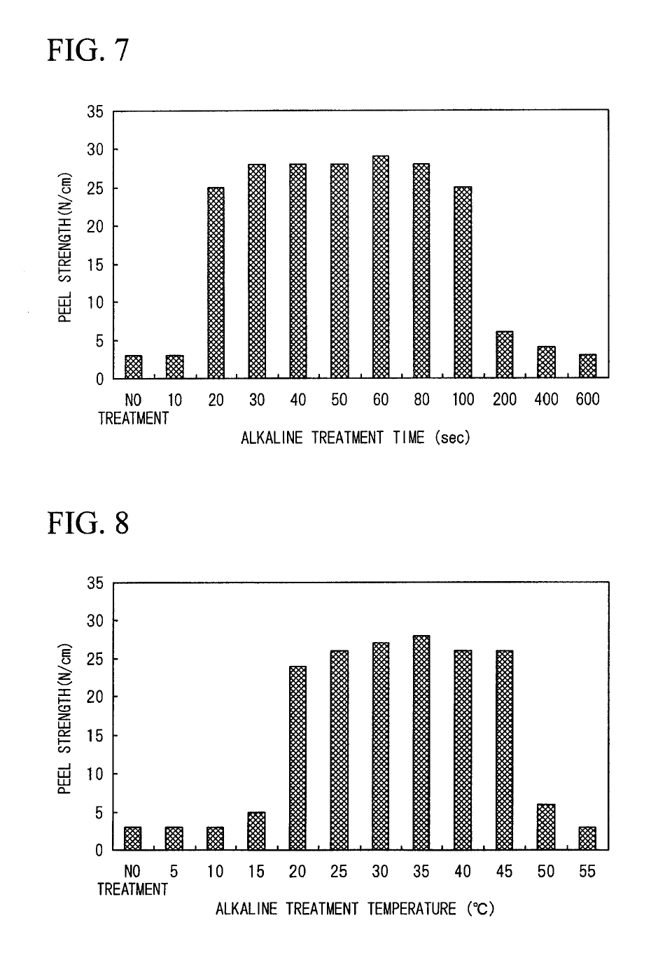

The mean value of measurement results for the four sites was taken from each sample as peel strength of the samples. For treatment conditions of the samples, with the number (N) of samples 40, peel strength of the each sample was measured and mean values of measurement results were taken as peel strength for each treatment condition.
A test example of Example 1 is shown in a graph of FIG. 6 (hereinafter referred to as graph 1).
A test example of Example 2 is shown in a graph of FIG. 7 (hereinafter referred to as graph 2).
A test example of Example 3 is shown in a graph of FIG. 8 (hereinafter referred to as graph 3).
Peel strength in a case where no alkaline treatment is carried out (no treatment) is shown for comparison in FIGS. 6 to 8.

### CONCLUSION

The following points are apparent from graph 1.

(1a) If the concentration of the alkaline solution is 0.1 wt % or less, the alkaline treatment is insufficient in that the peel strength is low.

(1b) If the concentration of the alkaline solution is 8.0 wt % or more, the alkaline treatment is excessive in that the peel strength is low.

(1c) If the concentration of the alkaline solution is 0.2 wt % or more and less than 8.0 wt %, the alkaline treatment is effective in that the peel strength is high. In particular, if the concentration of the alkaline solution is 0.2 wt % or more and 6.0 wt % or less, it is preferable in that the peel strength of about six times higher than that with no treatment can be stably obtained.

Accordingly, in order that a multi-layered FPC has a more stable peel strength, it can be seen that the concentration of the alkaline solution needs to fall within an appropriate range.

The following points are apparent from graph 2.

(2a) If the alkaline treatment time is 10 seconds or less, the alkaline treatment is insufficient in that the peel strength is low.

(2b) If the alkaline treatment time is 200 seconds or more, the alkaline treatment is excessive in that the peel strength is low.

(2c) If the alkaline treatment time is 20 seconds or more and less than 200 seconds, the alkaline treatment is effective in that the peel strength is high. In particular, if the alkaline treatment time is 20 seconds or more and 100 seconds or less, it is preferable in that the peel strength of about five times higher than that with no treatment can be stably obtained.

Accordingly, in order that a multi-layered FPC has a more stable peel strength, it can be seen that the alkaline treatment time needs to fall within an appropriate range.

The following points are apparent from graph 3.

(3a) If the temperature of the alkaline solution is 15° C. or less, the alkaline treatment is insufficient in that the peel strength is low.

(3b) If the temperature of the alkaline solution is 50° C. or more, the alkaline treatment is excessive in that the peel strength is low.

(3c) If the temperature of the alkaline solution is 20° C. or more and less than 50° C., the alkaline treatment is effective in that the peel strength is high. In particular, if the temperature of the alkaline solution is 20° C. or more and 45° C. or less, it is preferable in that the peel strength of about five times higher than that with no treatment can be stably obtained.

Accordingly, in order that a multi-layered FPC has a more stable peel strength, it can be seen that the temperature of the alkaline solution needs to fall within an appropriate range.

In general, it is known that a multi-layered FPC having low peel strength is low in reliability in various reliability tests including a heat cycle test, a heat shock test (in a vapor phase or a liquid phase), a pressure cooker test (PCT), a HAST test, a reflow test, etc. In other words, in a test in which deterioration of a multi-layered FPC is accelerated due to change in temperature, humidity and pressure, low peel strength is equivalent to low adhesion at particular sites, and consequently, it is obvious that the particular sites are likely to be peeled off, which results in insufficient and poor insulation of copper circuits.

On the contrary, high peel strength is equivalent to high adhesion at particular sites, and consequently, it is obvious that the particular sites are hardly peeled off in various reliability tests. Accordingly, increase of peel strength contributes to increase of reliability of multi-layered FPC.

In addition, the interlayer adhesives used in the above-mentioned examples are not particularly limited as long as they have a function of attaching CCL, such as a prepreg or coverlay (CL) film.

The multi-layered flexible printed circuit board manufactured according to the invention is appropriate as a printed circuit board used for electronic devices and the like.

While exemplary embodiments of the invention have been described and illustrated above, it should be understood that these are exemplary of the invention and are not to be considered as limiting. Additions, omissions, substitutions, and other modifications can be made without departing from the spirit or scope of the invention. Accordingly, the invention is not to be considered as being limited by the foregoing description, and is only limited by the scope of the appended claims.

What is claimed is:

1. A method of manufacturing a multi-layered flexible printed circuit board, the method comprising:
laminating at least two flexible printed circuit boards,
wherein a side comprising a conductor circuit of at least one of the at least two flexible printed circuit boards is subject to an alkaline solution with a concentration of 0.2 to 6.0 wt % and a temperature of 20 to 45° C. under a treatment time of 20 to 100 seconds before the laminating.

2. The method of manufacturing a multi-layered flexible printed circuit board according to claim 1, wherein the at least two flexible printed circuit boards subject to the alkaline treatment are laminated by attachment using an interlayer adhesive.

3. The method of manufacturing a multi-layered flexible printed circuit board according to claim 1, wherein the flexible printed circuit boards subject to the alkaline treatment are laminated by attachment using a prepreg or coverlay film.

4. A method of manufacturing a multi-layered printed circuit board, the method comprising:
forming a first flexible printed circuit board;
forming a second flexible printed circuit board; and
laminating the first and second flexible printed circuit boards;
wherein the first flexible printed circuit board is subjected to an alkaline solution with a concentration of 0.2 to 6.0 wt % and a temperature of 20 to 45° C. under a treatment time of 20 to 100 seconds before the laminating.

5. The method of manufacturing a multi-layered flexible printed circuit board according to claim 4, wherein the first flexible circuit comprises a double sided copper clad laminate.

6. The method of manufacturing a multi-layered flexible printed circuit board according to claim 5, wherein the second flexible circuit comprises a single sided copper clad laminate.

7. The method of manufacturing a multi-layered flexible printed circuit board according to claim 4, wherein the second flexible circuit is subjected to an alkaline solution with a concentration of 0.2 to 6.0 wt % and a temperature of 20 to 45° C. under a treatment time of 20 to 100 seconds before the laminating.

8. The method of manufacturing a multi-layered flexible printed circuit board according to claim 7, wherein the first flexible circuit comprises a double sided copper clad laminate.

9. The method of manufacturing a multi-layered flexible printed circuit board according to claim 8, wherein the second flexible circuit comprises a single sided copper clad laminate.
